(19) United States
(12) Patent Application Publication
(10) Pub. No.: US 2012/0039040 A1
(43) Pub. Date: Feb. 16, 2012

(54) ELECTRONIC DEVICE AND INDUCTOR THEREOF

(75) Inventor: ZEU-CHIA TAN, Tu-Cheng (TW)

(73) Assignee: HON HAI PRECISION INDUSTRY CO., LTD., Tu-Cheng (TW)

(21) Appl. No.: 12/979,372

(22) Filed: Dec. 28, 2010

(30) Foreign Application Priority Data
Aug. 10, 2010 (TW) 99126687

(51) Int. Cl. H05K 7/20

(52) U.S. Cl. 361/695

(57) ABSTRACT

An electronic device includes an enclosure, a cooling fan and a circuit board received in the enclosure, and an inductor mounted on the circuit board. The cooling fan generates airflow to the inductor to dissipate heat therefrom. The inductor includes a casing and a coil assembly received in the casing. The inductor has at least one uneven outer surface.

### CROSS-REFERENCE TO RELATED APPLICATIONS

This application claims all benefits accruing under 35 U.S.C. §119 from Taiwanese Patent Application No. 99126687, filed on Aug. 10, 2010, in the Taiwan Intellectual Property Office, the contents of which are hereby incorporated by reference.

### BACKGROUND

1. Technical Field

The present disclosure relates to electronic devices, and more particularly to an inductor for an electronic device.

2. Description of Related Art

Inductors are used in electronic devices where current and voltage change with time due to their ability to delay and reshape alternating currents. Generally, the inductor generates heat during operation which requires immediate dissipation. As a heat dissipation efficiency of the inductor depends on an outer surface area thereof, a size of the inductor is typically increased to accelerate the heat dissipation, which deviates from compactness requirements for the electronic device.

Therefore, an improved inductor is desired to overcome the described limitations.

### BRIEF DESCRIPTION OF THE DRAWINGS

FIG. 1 is an assembled, isometric view of an electronic device incorporating a plurality of inductors in accordance with one embodiment of the present disclosure.

FIG. 2 is an inverted, exploded view of one inductor of the electronic device of FIG. 1.

### DETAILED DESCRIPTION

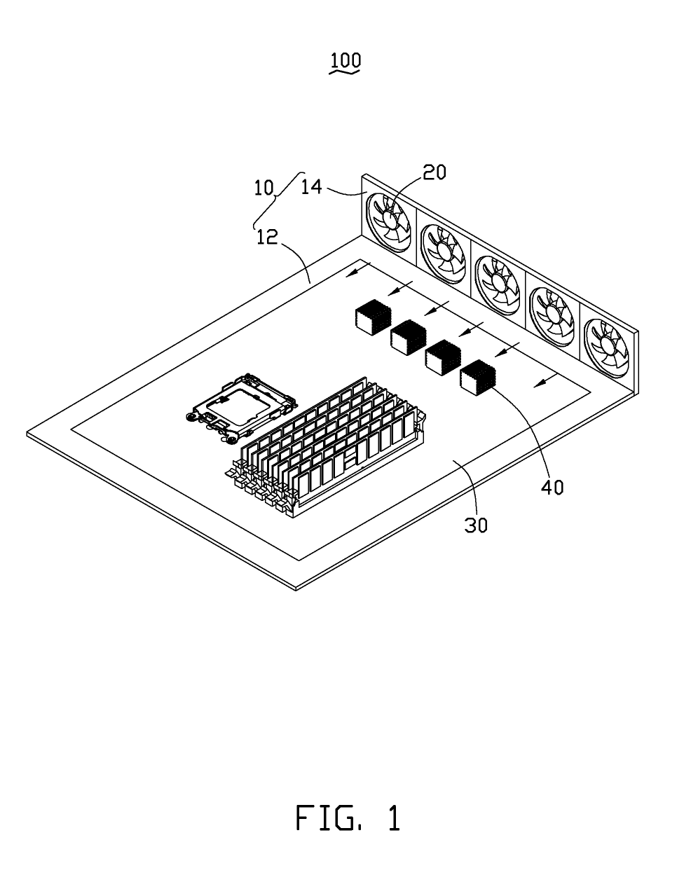

FIG. 1 shows an electronic device 100 including an enclosure 10, a plurality of cooling fans 20 mounted on the enclosure 10, a circuit board 30 received in the enclosure 10 and a plurality of inductors 40 mounted on the circuit board 30.

The enclosure 10 includes a substantially rectangular bottom panel 12 and four sidewalls extending upward from four edges of the bottom panel 12. In this FIG. only one sidewall 14 is shown and the others omitted for clarity. The circuit board 30 is attached to a top surface of the bottom panel 12. The inductors 40 and other electronic components (not labeled), such as central processing unit (CPU), Southbridge and Northbridge, are mounted on the circuit board 30. The cooling fans 20 are secured on the sidewall 14 and arranged in a line along the sidewall 14. The inductors 40 are arranged in front of the cooling fans 20. Airflow generated by the cooling fans 20 flows to the inductors 40 and the other electronic components to dissipate heat therefrom.

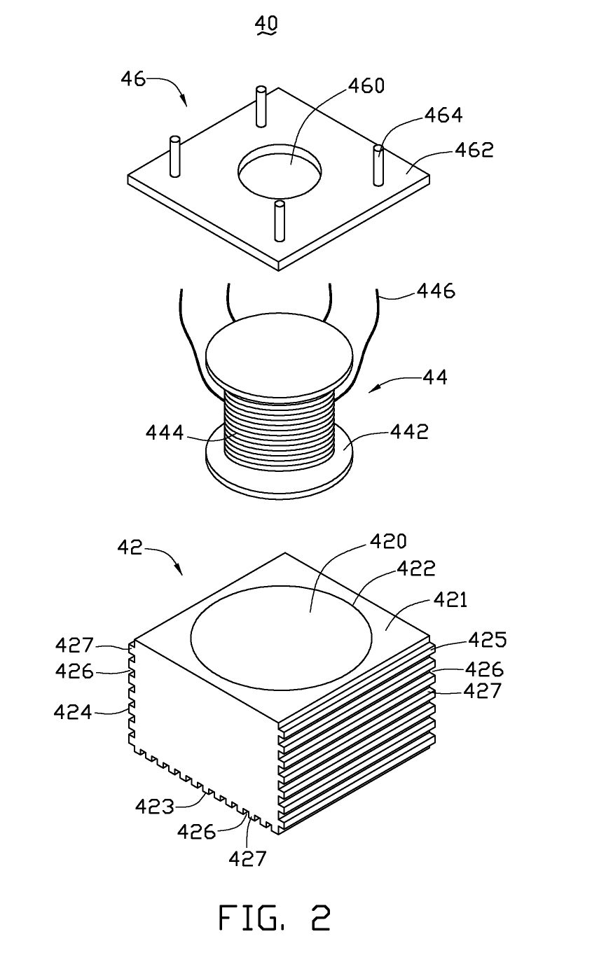

FIG. 2 is an inverted view of the inductor 40, so the following descriptions are based on the orientation indicated in FIG. 1.

The inductor 40 includes a casing 42, a coil assembly 44 received in the casing 42, and a bottom plate 46 attached to a bottom end of the casing 42. The casing 42 has a substantially cubic profile, and defines a substantially cylindrical receiving space 420 therein for receiving the coil assembly 44. The casing 42 defines an opening 422 at a bottom surface communicating with the receiving space 420 through which the coil assembly 44 enters the receiving space 420. A top surface 423, a left side surface 424, and a right side surface 425 of the casing 42, substantially parallel to the direction of airflow of the cooling fans 20, are uneven surfaces. More specifically, each of the top surface 423, the left side surface 424, and the right side surface 425 defines a plurality of linear grooves 426 therein. The grooves 426 are substantially parallel to and substantially equidistant from each other. Each groove 426 extends along the direction of the airflow of the cooling fans 20. A protruding rib 427 is thus formed between every two neighboring grooves 426. The grooves 426 and the protruding ribs 427 are alternately arranged.

The coil assembly 44 includes a core 442 and a plurality of coils 444 wound on the core 442. The core 442 is substantially cylindrical. A central section of the core 442 along an axis thereof has a diameter less than that of each of the top and bottom ends of the core 442. The coils 444 are wound on the central section of the core 442. The coils 444 form four free ends 446.

The bottom plate 46 includes a main body 462 and four pins 464 depending from a bottom side thereof. The main body 462 defines a through hole 462 at the center thereof. The pins 464 are respectively located at the corners of the main body 462.

In assembly of the inductor 40, the coil assembly 44 is received in the receiving space 420 of the casing 42. A top side of the bottom plate 46 is connected to the bottom end of the casing 42, with the through hole 460 of the bottom plate 46 aligned with the receiving space 420 of the casing 42. That is, the casing 42 and the pins 464 are respectively located at two opposite sides of the bottom plate 46. The free ends 446 of the coil assembly 44 extend through the through hole 460 of the bottom plate 46, and the free ends 446 are respectively connected with the pins 464 and electrically connected with the circuit board 30.

Because the grooves 426 are defined on the top surface 423, the left side surface 424, and the right side surface 425 of the inductor 40, an outer surface area of the inductor 40 is increased without increasing a size of the inductor 40. Accordingly, the heat dissipation efficiency of the inductor 40 is increased. In addition, the grooves 426 and the protruding ribs 427 of the inductor 40 extend along the direction of the airflow of the cooling fans 20, thereby facilitating airflow of the cooling fans 20 through the inductor 40. Furthermore, the grooves 426 and the protruding ribs 427 of the top surface 423, the left side surface 424 and the right side surface 426 extend along the same axis, thus the grooves 426 and the protruding ribs 427 of the three surfaces 423, 424, 425 can be formed simultaneously by molding or cutting. Accordingly, manufacturing cost of the inductor 40 remains low.

It is to be understood, however, that even though numerous characteristics and advantages of the disclosure have been set forth in the foregoing description, together with details of the structure and function of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
an enclosure;
a circuit board received in the enclosure;
an inductor mounted on the circuit board, the inductor comprising a casing and a coil assembly received in the casing, and having at least one uneven outer surface; and
a cooling fan mounted on the enclosure and generating airflow to the inductor.

2. The electronic device of claim 1, wherein the at least one outer surface of the inductor defines a plurality of spaced grooves therein.

3. The electronic device of claim 2, wherein the grooves are substantially equidistant from each other.

4. The electronic device of claim 2, wherein a protruding rib is formed between every two neighboring grooves of the at least one outer surface of the inductor.

5. The electronic device of claim 2, wherein the at least one outer surface is parallel to a direction of the airflow of the cooling fan.

6. The electronic device of claim 5, wherein the grooves each extend along the direction of the airflow of the cooling fan.

7. The electronic device of claim 2, wherein the grooves are defined in each of a top surface, a left-side surface, and a right-side surface of the inductor.

8. The electronic device of claim 2, wherein the inductor further comprises a bottom plate attached to a bottom of the casing, the bottom plate forms a plurality of pins thereon, the coil assembly comprises a core and a plurality of coils wound on the core, and the coils comprise a plurality of free ends connected with the pins of the bottom plate.

9. The electronic device of claim 8, wherein the casing and the pins are located at two opposite sides of the bottom plate, the bottom plate defines a through hole therein, and the free ends of the coils of the coil assembly extend through the through hole of the bottom plate to connect with the pins.

10. An inductor for an electronic device, the inductor comprising:
a casing defining a receiving space therein, and having at least one uneven outer surface;
a coil assembly received in the casing; and
a bottom plate attached to a bottom of the casing.

11. The inductor of claim 10, wherein the at least one outer surface of the inductor defines a plurality of spaced grooves therein.

12. The inductor of claim 11, wherein the grooves are substantially equidistant from each other.

13. The inductor of claim 11, wherein a protruding rib is formed between every two neighboring grooves of the at least one outer surface of the inductor.

14. The inductor of claim 11, wherein the grooves are defined in each of a top surface, a left-side surface, and a right-side surface of the inductor.

15. The inductor of claim 11, wherein the bottom plate forms a plurality of pins thereon, the coil assembly comprises a core and a plurality of coils wound on the core, and the coils comprise a plurality of free ends connected with the pins of the bottom plate.

16. The inductor of claim 15, wherein the casing and the pins are located at two opposite sides of the bottom plate, the bottom plate defines a through hole therein, and the free ends of the coils of the coil assembly extend through the through hole of the bottom plate to connect with the pins.
